(19) United States
(12) Patent Application Publication
(10) Pub. No.: US 2011/0066431 A1
(43) Pub. Date: Mar. 17, 2011

(54) HAND-HELD INPUT APPARATUS AND INPUT METHOD FOR INPUTTING DATA TO A REMOTE RECEIVING DEVICE

(75) Inventors: Shang-Tzu Ju, Hsinchu City (TW); Yu-Ping Ho, Kao-Hsiung Hsien (TW); Ching-Chieh Wang, Yilan County (TW)

(73) Assignee: MEDIATEK INC., Hsin-Chu (TW)

(21) Appl. No.: 12/786,780

(22) Filed: May 25, 2010

Related U.S. Application Data
(60) Provisional application No. 61/242,464, filed on Sep. 15, 2009.

(51) Int. Cl. H03K 17/94; G10L 15/26; G06F 3/041; G06F 17/21

(52) U.S. Cl. 704/235; 341/20; 345/173; 715/268; 704/E15.043

(57) ABSTRACT

A hand-held input apparatus includes an input unit, a translator and a wireless transmitter. The input unit generates an input signal. The translator receives the input signal from the input unit, converts the input signal to a meaningful text and translates the meaningful text to a translated signal according to a protocol used in a remote receiving device. The wireless transmitter wirelessly transmits the translated signal to the remote receiving device.

### CROSS REFERENCE TO RELATED APPILCATIONS

This Application claims priority of U.S. Provisional Application No. 61/242464, filed on Sep. 15, 2009, the entirety of which is incorporated by reference herein.

### BACKGROUND OF THE INVENTION

1. Field of the Invention

The invention relates to input apparatuses and methods using the same, and more particularly to hand-held input apparatuses and methods for inputting data to a remote receiving device via a wireless link.

2. Description of the Related Art

With the convenience of portable devices, such as mobile phones, PDAs, etc, one can easily carry a device when traveling. As technology advances, internet access through non-traditional means, such as TVs or portable devices, has become more popular. Devices, such as TVs, can be directly connected to networks to implement network applications. When surfing a network, for convenience, inputting data is desired by users. Moreover, personal data of users, such as passwords, identification card numbers, credit card numbers or bank account amounts, may be requested for input or reviewed when acquiring information through the internet.

However, it requires time to set up the aforementioned personal data of users.

### BRIEF SUMMARY OF THE INVENTION

Hand-held input apparatuses and input methods for inputting data to a remote receiving device are provided. An exemplary embodiment of a hand-held input apparatus includes an input unit, a translator and a wireless transmitter. The input unit generates an input signal. The translator receives the input signal from the input unit, converts the input signal to a meaningful text and translates the meaningful text to a translated signal according to a protocol used in a remote receiving device. The wireless transmitter wirelessly transmits the translated signal to the remote receiving device.

Moreover, an exemplary embodiment of a hand-held input apparatus, comprises a storage device, a translator and a wireless transmitter. The storage device stores at least a personal data. The translator is coupled to the storage device for obtaining the personal data from the storage device and translating the personal data to a translated signal according to a protocol used in a remote receiving device. The wireless transmitter wirelessly transmits the translated signal to the remote receiving device.

Furthermore, an exemplary embodiment of an input method for inputting data to a remote receiving device via a wireless link is provided. An input signal is translated to a translated signal according to a protocol used in the remote receiving device. Next, the translated signal is wirelessly transmitted to the remote receiving device via the wireless link.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a schematic diagram illustrating a hand-held input apparatus according to an embodiment of the invention;

FIG. 2 is a flowchart showing an embodiment of a method for inputting data to the remote receiving device according to the invention;

FIG. 3 is a flowchart showing an embodiment of a method for inputting data to the remote receiving device according to the invention;

FIG. 4 is a flowchart showing an embodiment of a method for inputting data to the remote receiving device according to the invention;

FIG. 5 is a flowchart showing another embodiment of a method for inputting data to the remote receiving device according to the invention; and

FIG. 6 is a flowchart showing yet another embodiment of a method for inputting data to the remote receiving device according to the invention.

### DETAILED DESCRIPTION OF THE INVENTION

The following description is of the best-contemplated mode of carrying out the invention. The description is made for the purpose of illustrating the general principles of the invention and should not be taken in a limiting sense. The scope of the invention is best determined by reference to the appended claims.

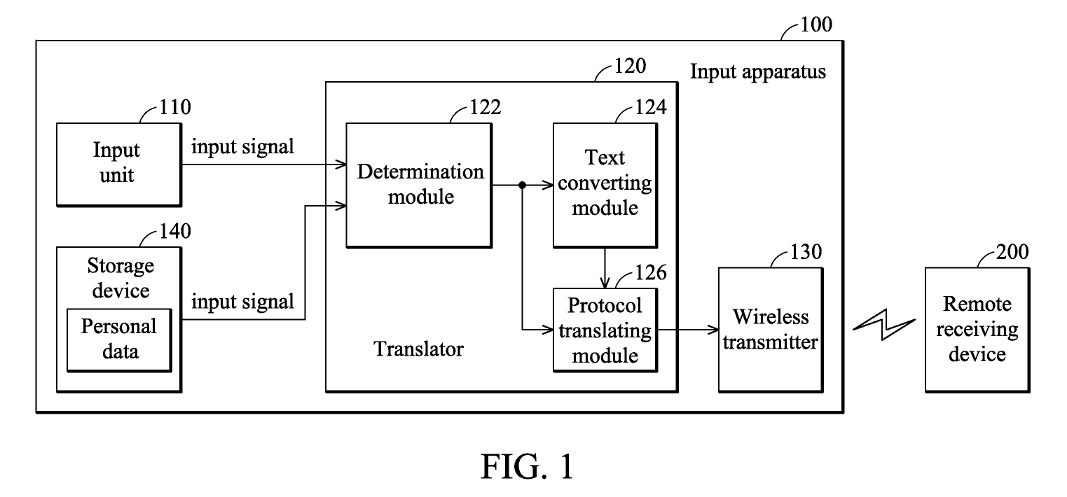

FIG. 1 is a schematic diagram illustrating a hand-held input apparatus 100 according to an embodiment of the invention. The hand-held input apparatus 100 may be a portable device, such as a mobile phone, a PDA, etc. As shown in FIG. 1, the hand-held input apparatus 100 may wirelessly communicate with a remote receiving device 200 (e.g. a television (TV), a display device or a display device allowing internet access) using wireless communication techniques such as wireless local area network (WLAN), Bluetooth, worldwide interoperability for microwave access (WiMAX), long term evolution (LTE), infrared data association (IrDA), etc. In one embodiment, the remote receiving device 200 is not a computer. The hand-held input apparatus 100 comprises an input unit 110, a translator 120, a wireless transmitter 130 and a storage device 140.

Users may input data by the input unit 110. The input unit 110 may be capable of receiving various inputs to generate an input signal. The input unit 110 may be, for example but not limited to, a physical or virtual keypad, an audio input unit for receiving an audio signal, a touch panel or a combination thereof. In one embodiment, the touch panel supports handwritten text. The translator 120 may receive the input signal and convert the input signal to a meaningful text and translates the meaningful text to a translated signal according to a protocol used in a remote receiving device 200. In other words, the translator 120 is capable of translating the input signal to a signal that the remote receiving device 200 may read or accept so that the translated signal can be processed at the remote receiving device 200 end.

The translator 120 may comprise a determination module 122, a text converting module 124 and a protocol translating module 126. The determination module 122 determines whether to convert the input signal to a text according to the input signal. In one embodiment, the input unit 110 includes a keypad, an audio input unit, a touch panel or a combination thereof, and thus the input signal is a key input signal or a non-key input signal. Then the determination module 120 may pass the input signal to the text converting module 124 to convert the input signal to a meaningful text. In one embodiment, the input unit 110 may include a user interface for configuring or selecting a control command to generate a control signal as the input signal. The determination module 122 will directly pass the input signal to the protocol translating module 126. In another embodiment, the input signal is a personal data stored in the storage device 140, and the determination module 122 will directly pass the input signal to the protocol translating module 126. After receiving the meaningful text and/or the input signal, the protocol translating module 126 may translate the meaningful text and/or the input signal according to a protocol used in the remote receiving device 200 to generate a translated signal.

The text converting module 124 may be an input method editor (IME) that is configured to generate at least one character to form the meaningful text in response to the input signal. An IME is a program that allows users to enter complex characters and symbols, such as Japanese characters, Chinese characters, and Korean characters using a keyboard. Using the IMEs, users can input such as Chinese, Japanese and/or Korean text directly into applications, web forms, and e-mail messages using the keyboard. The IME may comprise at least two types of input methods for user selection such as Boshiamy method, Pinyin method, Cangjie method, etc, and the input method editor may then generate the at least one character according to the selected type of the input method. For example, if a first type of input method is selected by the user, the input method editor may then generate the at least one character according to the first type of input method.

In one embodiment, the input unit 110 may include an audio input unit (e.g. a microphone) for receiving an audio signal to generate the input signal. The text converting module 124 may comprise a speech recognition module that is configured to receive the input signal from the audio input unit and in response to the input signal generates at least one character to form the meaningful text. In another embodiment, the input unit 110 may include a touch panel supporting handwritten text. The text converting module 124 may include a handwriting recognition module that is configured to generate at least one character to form the meaningful text in response to the input signal.

After the translated signal is generated by the protocol translating module 126, the wireless transmitter 130 may wirelessly transmit the translated signal to the remote receiving device 200. The storage device 140 may store personal data such as bookmarks, email addresses, address books, the like or a combination thereof. The personal data may further include, for example, multimedia data, such as an image file, but it is not limited thereto.

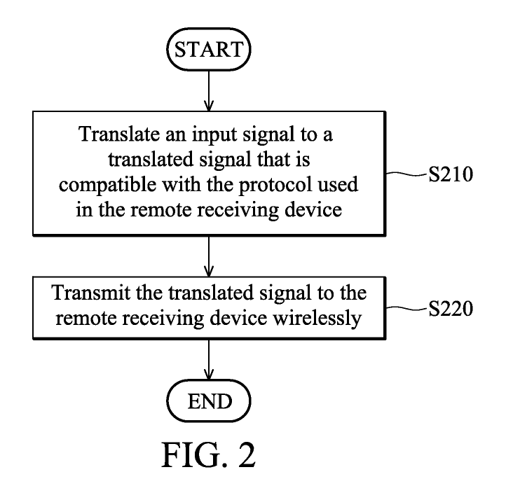

FIG. 2 is a flowchart showing an embodiment of a method for inputting data to the remote receiving device according to the invention. The method can be applied in the apparatus 100. In step S210, an input signal is translated to a translated signal that is compatible with the protocol used in the remote receiving device 200. It is understood that the input signal may include, but not limited to, a key input signal, a non-key input signal, control information such as control commands selected or issued by the user, personal data of the user stored in the storage device 140 or a combination thereof. The key input signal could be generated by the input unit 110 such as a physical or virtual keypad. The non-key input signal could be generated by the input unit 110 such as a touch panel or an audio input unit. The control information could be generated by the input unit 110 such as a user interface. As to the translation, for example, if a Bluetooth protocol is used in the remote receiving device 200, the input signal is translated to a translated signal which is compatible with the Bluetooth protocol. After the translated signal is generated, in step S220, the translated signal may be transmitted to the remote receiving device 200 wirelessly. The translated signal may be transmitted to the remote receiving device 200 wirelessly by the wireless transmitter 130. As the translated signal matches the protocol used in the remote receiving device 200, the remote receiving device 200 may translate the translated signal to a corresponding input data for the remote receiving device 200.

Several examples of inputting data to the remote receiving device are provided.

In one embodiment, the apparatus 100 may transmit text generated by a keypad to the remote receiving device 200.

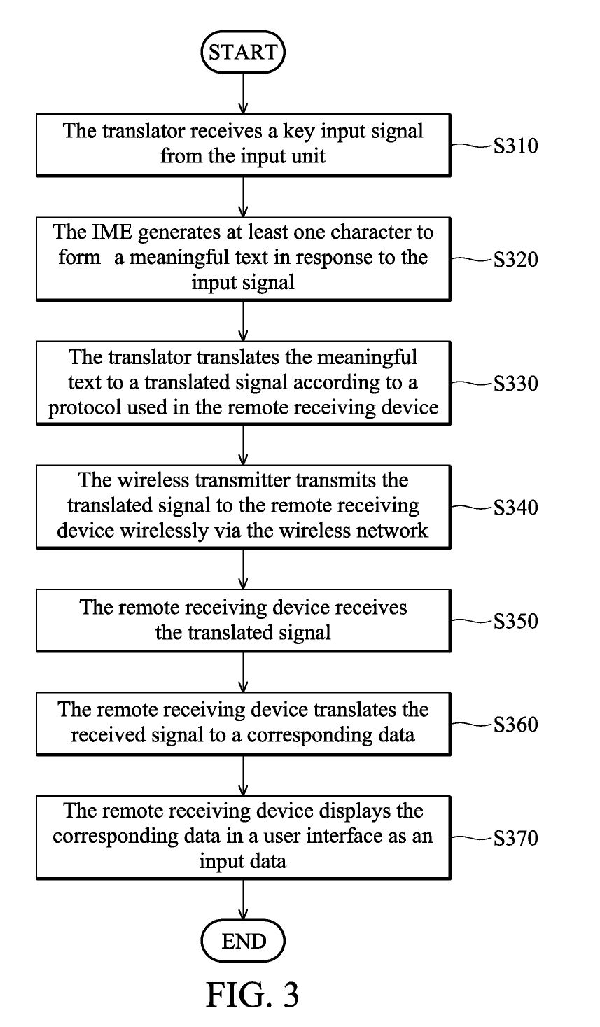

FIG. 3 is a flowchart showing an embodiment of a first method for inputting data to the remote receiving device according to the invention. The first method can be applied in the apparatus 100. In step S310, the translator 120 receives a key input signal from the input unit 110. In this embodiment, the input unit 110 could be a physical or virtual keypad. In step S320, the IME generates at least one character to form a meaningful text in response to the input signal. Then, in step S330, the translator 120 translates the meaningful text to a translated signal according to a protocol used in a remote receiving device 200. It is understood that the protocol used in the remote receiving device 200 could include wireless local area network (WLAN), Bluetooth, worldwide interoperability for microwave access (WiMAX), long term evolution (LTE), infrared data association (IrDA) or a combination thereof, but it's not limited thereto. For example, if the remote receiving device 200 uses a Bluetooth protocol, the translator is capable of translating the meaningful text to a translated signal with the same protocol as the remote receiving device 200, i.e. the Bluetooth protocol. After generating the translated signal, in step S340, the wireless transmitter 130 may transmit the translated signal to the remote receiving device 200 wirelessly via the wireless network. Thus, in step S350, the translated signal will then be received by the remote receiving device 200. After receiving the translated signal, in step S360, the remote receiving device 200 may translate the signal to a corresponding data such as words and, in step S370, display the corresponding data such as words in a user interface as an input data.

In another embodiment, the apparatus 100 may transmit text generated by the input unit 110 including non-key input devices such as an audio input unit or a touch panel to the remote receiving device 200.

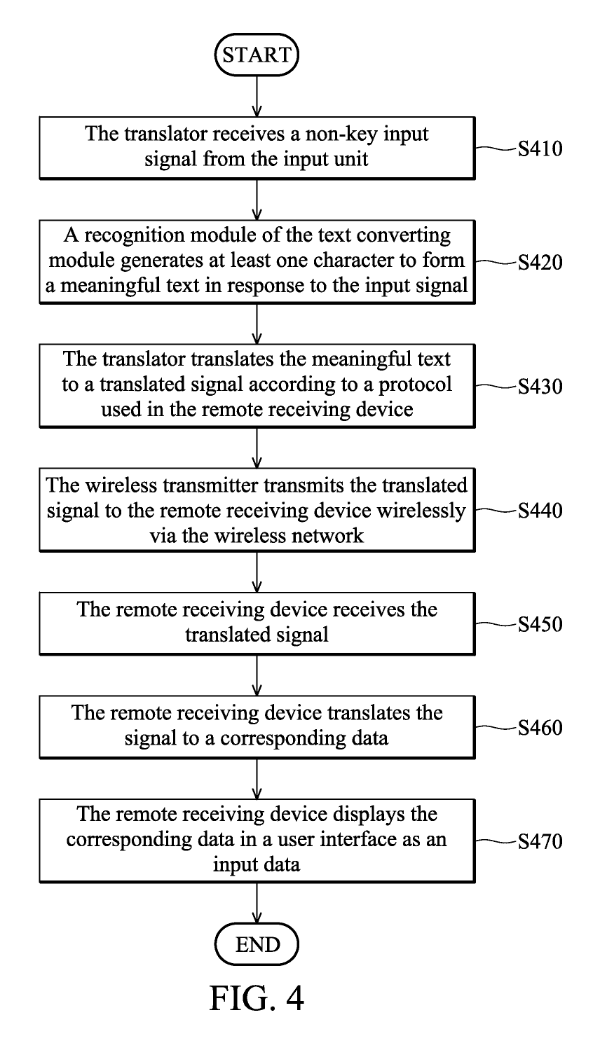

FIG. 4 is a flowchart showing an embodiment of a second method for inputting data to the remote receiving device according to the invention. The second method can be applied in the apparatus 100. In step S410, the translator 120 receives a non-key input signal from the input unit 110. In this embodiment, the input unit 110 could be an audio input unit (e.g. a microphone) or a touch panel. In step S420, a recognition module (not shown) of the text converting module 124 generates at least one character to form a meaningful text in response to the input signal. The recognition module could be a speech recognition module if the input unit 110 includes an audio input unit. The recognition module could be a handwriting recognition module if the input unit 110 includes a touch panel supporting handwritten text. Then, in step S430, the translator 120 translates the meaningful text to a translated signal according to a protocol used in the remote receiving device 200. It is understood that the protocol used in the remote receiving device 200 could include wireless local area network (WLAN), Bluetooth, worldwide interoperability for microwave access (WiMAX), long term evolution (LTE), infrared data association (IrDA) or a combination thereof, but it's not limited thereto. For example, if the remote receiving device 200 uses a IEEE 802.1x compatible protocol, the translator is capable of translating the meaningful text to a translated signal with the same protocol as the remote receiving device 200, i.e. the IEEE 802.1x compatible protocol. After generating the translated signal, in step S440, the wireless transmitter 130 may transmit the translated signal to the remote receiving device 200 wirelessly via the wireless network. Thus, in step S450, the translated signal will then be received by the remote receiving device 200. After receiving the translated signal, in step S460, the remote receiving device 200 may translate the signal to a corresponding data such as words and, in step S470, display the corresponding data such as words in a user interface as an input data.

In another embodiment, the apparatus 100 may further transmit personal data to the remote receiving device 200.

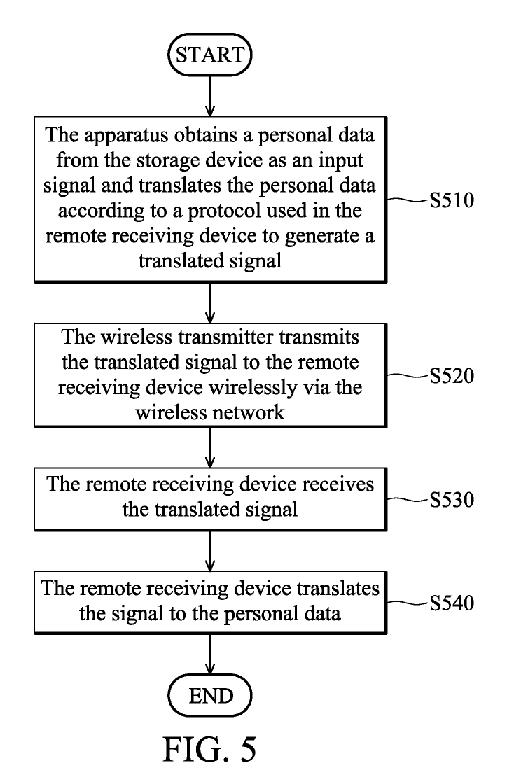

FIG. 5 is a flowchart showing another embodiment of a third method for inputting data to the remote receiving device according to the invention. The third method can be applied in the apparatus 100. In this embodiment, personal data, e.g. bookmarks, email addresses, address books and the others, is stored in the storage device 140 of the apparatus 100. In step S510, the apparatus 100 obtains the personal data from the storage device 140 as an input signal and translates the personal data according to a protocol used in the remote receiving device 200 to generate a translated signal. After generating the translated signal, in step S520, the wireless transmitter 130 may transmit the translated signal to the remote receiving device 200 wirelessly via the wireless network. Thus, in step S530, the translated signal will then be received by the remote receiving device 200. After receiving the translated signal, in step S540, the remote receiving device 200 may translate the signal to obtain the personal data.

In yet another embodiment, the input unit 110 may further be an user interface for configuring or selecting a control command to generate a control signal as an input signal and the apparatus 100 may further be used to control an application on the remote receiving device 200, such as “open IE”, “open E-mail” and so on, by sending a control command corresponding to the application to the remote receiving device 200 via the user interface. For example, the apparatus 100 may select or send an Open_IE command for requesting the remote receiving device 200 to open an IE application.

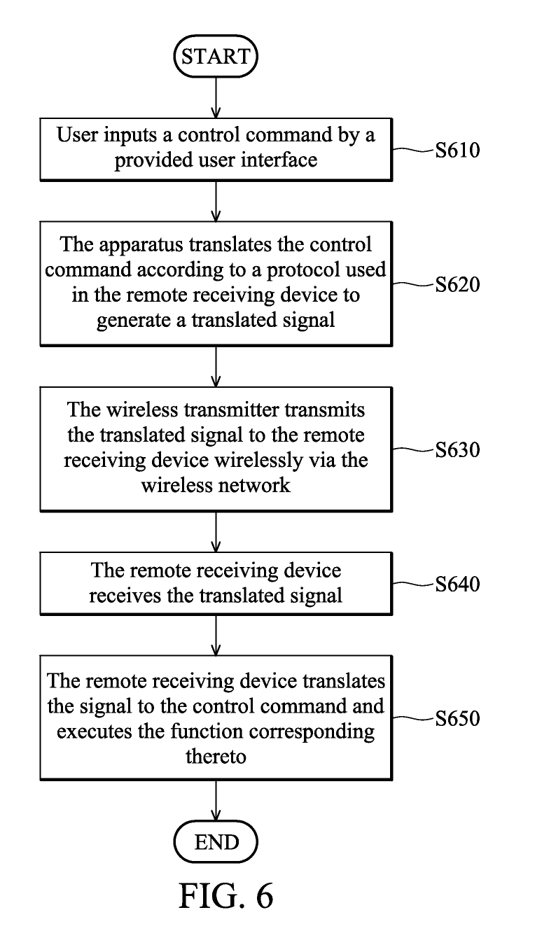

FIG. 6 is a flowchart showing yet another embodiment of a fourth method for inputting data to the remote receiving device according to the invention. The fourth method can be applied in the apparatus 100. In this embodiment, a user attempts to control an application such as an IE application on the remote receiving device 200. Thus, in step S610, a user inputs a control command by a provided user interface. In step S620, the apparatus 100 translates the control command according to a protocol used in the remote receiving device 200 to generate a translated signal. After generating the translated signal, in step S630, the wireless transmitter 130 may transmit the translated signal to the remote receiving device 200 wirelessly via the wireless network. Thus, in step S640, the translated signal will then be received by the remote receiving device 200. After receiving the translated signal, in step S650, the remote receiving device 200 may translate the signal to the control command and execute the function corresponding thereto.

It should be noted that the embodiments of methods shown in FIGS. 2-6 are only illustrative and not intended to be limitation. The order of the steps could be modified and steps could be omitted according to design requirements. According to the hand-held input apparatus and related input method of the invention, for inputting data to a remote receiving device such as a TV, a display device or a display device allowing internet access, users may edit text using their own IME or input units on the hand-held input apparatus and then transmit the text to the remote receiving device as the input data without adding any extra feature to the receiving device. Thus, user convenience is enhanced. Moreover, users may also transmit personal data such as bookmarks, e-mail addresses, image files, etc. to the remote receiving device directly. In addition, users may also control the application of the remote receiving device by using the input apparatus to send control commands.

Methods for inputting data to the remote receiving device, or certain aspects or portions thereof, may take the form of program code (i.e., executable instructions) embodied in tangible media, such as products, floppy diskettes, CD-ROMS, hard drives, or any other machine-readable storage medium, wherein, when the program code is loaded into and executed by a machine, such as a computer, the machine thereby becomes an apparatus for practicing the methods. The methods may also be embodied in the form of program code transmitted over some transmission medium, such as electrical wiring or cabling, through fiber optics, or via any other form of transmission, wherein, when the program code is received and loaded into and executed by a machine, such as a computer, the machine becomes an apparatus for practicing the disclosed methods. When implemented on a general-purpose processor, the program code combines with the processor to provide a unique apparatus that operates analogously to application specific logic circuits.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the invention shall be defined and protected by the following claims and their equivalents.

What is claimed is:

1. A hand-held input apparatus, comprising:
an input unit, generating an input signal;
a translator, receiving the input signal from the input unit, converting the input signal to a meaningful text and translating the meaningful text to a translated signal according to a protocol used in a remote receiving device; and
a wireless transmitter, wirelessly transmitting the translated signal to the remote receiving device.

2. The hand-held input apparatus as claimed in claim 1, wherein the input unit is a physical or virtual keypad and the translator comprises a text converting module for converting the input signal to the meaningful text.

3. The hand-held input apparatus as claimed in claim 2, wherein the text converting module is an input method editor (IME) that is configured to generate at least one character to form the meaningful text in response to the input signal.

4. The hand-held input apparatus as claimed in claim 3, wherein the input method editor comprises at least two types of input methods for user selection, and the input method editor generates the at least one character according to the selected type of the input method.

5. The hand-held input apparatus as claimed in claim 1, wherein the input unit is an audio input unit for receiving an audio signal to generate the input signal and the translator comprises a text converting module for converting the input signal to the meaningful text.

6. The hand-held input apparatus as claimed in claim 5, wherein the text converting module is a speech recognition module that is configured to generate at least one character to form the meaningful text in response to the input signal.

7. The hand-held input apparatus as claimed in claim 1, wherein the input unit is a touch panel supporting handwritten text and the translator comprises a text converting module for converting the input signal to the meaningful text.

8. The hand-held input apparatus as claimed in claim 7, wherein the text converting module is a handwriting recognition module that is configured to generate at least one character to form the meaningful text in response to the input signal.

9. The hand-held input apparatus as claimed in claim 1, wherein the input signal is a control signal for controlling an application on the remote receiving device, and the translator translates the control signal to the translated signal according to the protocol used in the remote receiving device without converting the input signal to a meaningful text.

10. The hand-held input apparatus as claimed in claim 9, wherein the input unit is a user interface for configuring or selecting a control command to generate the control signal.

11. A hand-held input apparatus, comprising:
a storage device, storing at least a personal data;
a translator coupled to the storage device, obtaining the personal data from the storage device and translating the personal data to a translated signal according to a protocol used in a remote receiving device; and
a wireless transmitter, wirelessly transmitting the translated signal to the remote receiving device.

12. The hand-held input apparatus as claimed in claim 11, wherein the personal data comprises at least one of bookmarks, email addresses and address books.

13. The hand-held input apparatus as claimed in claim 11, wherein the personal data comprises an image file.

14. The hand-held input apparatus as claimed in claim 11, wherein the hand-held input apparatus is a mobile phone, a PDA or a combination thereof

15. The hand-held input apparatus as claimed in claim 11, wherein the remote receiving device is a television.

16. An input method for inputting data to a remote receiving device via a wireless link, comprising:
translating an input signal to a translated signal according to a protocol used in the remote receiving device; and
wirelessly transmitting the translated signal to the remote receiving device via the wireless link.

17. The input method as claimed in claim 16, wherein translating an input signal to a translated signal according to a protocol used in a remote receiving device comprises:
receiving the input signal from an input unit;
converting the input signal to a meaningful text; and
translating the meaningful text to the translated signal according to the protocol used in the remote receiving device.

18. The input method as claimed in claim 17, wherein the input unit is a physical or virtual keypad and the step of converting the input signal to a meaningful text comprises:
using an input method editor (IME) to generate at least one character to form the meaningful text in response to the input signal.

19. The input method as claimed in claim 17, wherein the input unit is an audio input unit for receiving an audio signal to generate the input signal, and the step of converting the input signal to a meaningful text comprises:
using a speech recognition module to generate at least one character to form the meaningful text in response to the input signal.

20. The input method as claimed in claim 17, wherein the input unit is a touch panel supporting handwritten text and the step of converting the input signal to a meaningful text comprises:
using a handwriting recognition module to generate at least one character to form the meaningful text in response to the input signal.

21. The input method as claimed in claim 16, further comprising:
obtaining a personal data from a storage device as the input signal.

22. The input method as claimed in claim 16, wherein the input signal is a control signal for controlling an application on the remote receiving device, and the method further comprises:
activating the application on the remote receiving device according to the translated signal.
